(19) United States
(12) Patent Application Publication
(10) Pub. No.: US 2003/0010892 A1
(43) Pub. Date: Jan. 16, 2003

(54) Imaging system using identical or nearly-identical scanning and viewing illuminations

(76) Inventor: Lloyd Douglas Clark, San Francisco, CA (US)

Correspondence Address: LLOYD DOUGLAS CLARK, 15 CONRAD ST., SAN FRANCISCO, CA, 94131, US

(21) Appl. No.: 09/894,614

(22) Filed: Jun. 27, 2001

(51) Int. Cl. H01L 27/00

(52) U.S. Cl. 250/208.1

(57) ABSTRACT

An organic light emitting diode (OLED) array (800) is used in conjunction with a computer (155) and an OLED screen (161) to scan and view an object (100 or 230). The array and screen both have the same red, green, and blue OLED emitters of substantially the same wavelengths and bandwidths. Thus the image is reconstructed on the viewing screen with the same wavelengths used when it was scanned. This substantially reduces the requirement for device profiling, with its attendant inaccuracies and errors. Replacing the fluorescent lamp (110) with an OLED array eliminates flicker (changes in intensity with time), thus extending the dynamic range of the scanner significantly beyond eight bits. Adding non-imaging optics (1100) to the OLED array increases the intensity of light available for scanning.

### FEDERALLY SPONSORED RESEARCH

None

### Sequence Listing—None

### Background—Field of Invention

This invention relates generally to the scanning and viewing of image information. In particular, the invention relates to scanning and viewing an image using polychromatic light sources with identical or nearly identical spectral characteristics.

### Background—Prior-Art—Reflective Flatbed Scanners—FIG. 1

The main elements of a flatbed scanner are well-known. They are shown in cross-section in FIG. 1. An object to be scanned 100 is placed face-down on a transparent, glass platen 105. Illumination from source 110 is directed at a reflector 115 which in turn illuminates object 100 with incident light rays 120. Light block 121 blocks stray light from source 110, preventing exposure of detector 150 to direct radiation from source 110. Rays 125 are reflected from object 100 onto mirrors 130, 135, and 140 on their way to lens 145. Lens 145 focuses rays 125 onto image detector 150, which comprises one or more linear charge-coupled devices, Complementary Metal-Oxide Semiconductor (CMOS) imaging chips, or the like.

An image is scanned one line at a time, normally starting at one end. Source 110 is energized by a power supply (not shown). Source 110, reflector 115, and mirror 130 are moved to one end of the image. Mirrors 135 and 140 are moved to a position intermediate source 110 and the end of platen 105. Detector 150 detects the image information in this line and sends the information on to computer or storage unit 155 where the first line of data is corrected, as described below, and stored. Source 110, reflector 115, and mirror 130 are then moved, typically 0.006 cm, down platen 105. Mirrors 135 and 140 are moved to a new intermediate position between source 110 and the end of platen 105. Then another line of data is detected and sent to computer or storage device 155, corrected (as described below), and so on until the scan is complete. At an image resolution of 118 picture elements (pixels) per cm, a line scan 20.3 cm wide contains typically 2,400 picture elements (pixels). A scan which is 27.9 cm long contains 3,290 lines. The total number of picture elements for which data are saved in computer or storage unit 155 is thus 7,896,000, assuming only monochrome data is saved. For eight-bit data, this amounts to about 7.9 megabytes. Stored images are viewed on screen 161 of monitor 160.

Source 110 is typically a fluorescent lamp. The light output from fluorescent lamps is typically unsteady, resulting in flicker (higher and lower intensity levels) at a rate of many times per second. To reduce the effect of flicker, most flatbed scanners scan a white flicker-correction strip (not shown) adjacent one side of platen 105. The intensity of light reflected from this strip should be constant. Deviations in the measured intensity of the white flicker-correction strip are noted for each line scan. The inverse of these deviations are multiplicatively applied to data sent from the scanner to computer or storage device 155 in well-known fashion. This reduces the effect of flicker. However, even when so reduced, flicker is still present and it limits the digital depth or precision of data available from most flatbed scanners to 8 bits, or one part in 256, unless otherwise corrected with image processing algorithms. “Eight-bit” numbers represent a precision of one part in 256. “Twelve-bit” numbers represent a precision of one part in 4096, and so forth. The greater the precision, the greater the quality of the saved image. This eight-bit limitation caused by flicker prevents the user from obtaining true, high-fidelity images, even though detector 150 is capable of greater precision, in many cases up to 12 bits.

Power supplies for fluorescent lamps used in prior-art scanners are expensive. To obtain as much light as possible from a fluorescent lamp, it is driven by high voltage, typically several hundred volts, and at a high frequency, typically several hundred kilohertz. These power supplies add cost and complexity to scanners in which they are used.

Intensity of light output from a new fluorescent lamp is typically 15,000 candelas per meter squared (cd/m²). The color of the light is determined by the mixture of fluorescent phosphors used. As the lamp ages, its intensity decreases. In some cases, the color of the lamp also changes slightly with time as certain phosphors in the mixture age more rapidly than others.

### Background—Prior-Art—Transmissive Film Scanners—FIG. 2

Another type of scanner is a transmissive film scanner, the main elements of which are shown in cross-section in FIG. 2. Such scanners are well-known to those skilled in the art of scanning film images. A light source or lamp 110, typically a fluorescent lamp, is energized by a power supply (not shown). Light rays 205 leave lamp 110 and are focused on translucent film 210 by lens 215. A reflector 207 reflects light from the back side of lamp 110 into lens 215. This light would otherwise be lost. A second lens 220, focused on the opposite side of film 210, collects light rays 205 transmitted through film 210 and delivers a focused image onto a linear charge-coupled device (CCD), CMOS imager, or other imager 225. CCDs and CMOS imagers are well-known to those skilled in electronics and optics. Film 210 is moved in the focal plane between lenses 215 and 220 by a transport mechanism (not shown) whose actuation is synchronized by electronics (not shown) with the operation of imager 225. Film 210 is first positioned so that end 230 is illuminated by lens 215 and imaged by lens 220 onto imager 225. A line of data is detected by imager 225, converted to electrical signals, and transmitted to computer 155, where it is stored in the computer's memory (not shown). Image data are typically saved as eight-bit to twelve-bit numbers in the memory of computer 245. Film 210 is then moved downward a distance equal to one scan line (typically 0.005 cm) and another line of data is detected, converted, and stored. This process continues until the entire image on film 210 is scanned and stored. The volume of data saved by transmissive scanners is typically the same or more than for a flatbed. Stored images are viewed on screen 161 of monitor 160.

As with the flatbed scanner, the quality of illumination from source 110 determines the quality of image saved in the memory of computer 245. Fluorescent flicker is still a limiting factor. The power supplies used are again complex and costly.

### Background—Prior-Art—Color Scanning—FIG. 3

Most prior-art scanners are used to scan color images. This is normally done by scanning each line more than once. In most color scanners, whether reflective or transmissive, white light normally illuminates the object being scanned. Color filters are employed to sample the image at multiple wavelengths in the visible spectrum. Red, green, and blue filters are normally used. For example, a first line is typically scanned through a red filter, then through a green filter, then through a blue filter. The scanner then moves either the optics or the object a small distance, as described above, and repeats this process. This results in a data set which is three times as large as for the monochrome scans discussed above; one scan each for red, green, and blue. Full-size color scans generally occupy from 20 to 128 megabytes of data.

Data are viewed on computer monitors, television screens, and the like, which emit light from red, green, and blue phosphors. Circuitry inside the monitor or television converts the stored data for each pixel to voltages which drive the screen of the device.

In the past, color scanners placed filters sequentially between illumination source 110 and object 100 (FIG. 1) or film 210 (FIG. 2) being scanned. First, object 100 was illuminated by light passed through a red filter (not shown) and a line of red-illuminated data was detected and saved in computer or storage unit 155. Next, this step was repeated by shining light from source 110 through a green filter (not shown), and finally a blue filter (not shown). Thus each pixel in the image was represented by three bytes of data, one each for red, green, and blue. These scanners used fluorescent illumination, with its attendant problem of flicker and therefore limited precision. Fluorescent lamp power supplies were also costly and complex.

Later scanners employ semiconductor image sensors with integral color filters. These filters are placed directly on the face of the sensor. The illumination source 110 in these scanners is white light. Three image sensors are used to capture the image a line at a time, as described above. Data for each pixel in the scanned object are saved as before. These image sensors are expensive and complicated to manufacture.

With all prior-art filtered light systems, a significant variable is introduced by the choice of color filters. The performance of each color filter is specified by its center wavelength and passband. (Although somewhat important, the shape of the passband will be ignored here in the interest of simplicity.) For purposes of the present discussion, the passband of a filter will be defined as the difference between the highest and lowest wavelengths at which the filter passes 50% of the incident light incident on it. FIG. 3 shows the normalized characteristics of three color filters, blue, green, and red. The filter characteristic of the blue filter in FIG. 3 is described as follows: the center wavelength is 450 nanometers (nm), and the passband is 440-460 nm. Similarly, the green filter is described as having a center wavelength of 540 nm and a passband of 530-550 nm, and the red filter has a center wavelength of 610 nm with a passband of 600 to 620 nm.

There is wide variability in the characteristics of color filters used by different manufacturers. The characteristics of filters applied to optical sensors vary from manufacturer to manufacturer. The characteristics of filters (not shown) used between illumination source 110 and optical sensor 155 also vary from manufacturer to manufacturer. The manufacture of filters is beyond the scope of this discussion. However, numerous different materials, treatments of these materials, and constructions are used in the manufacture of filters. The center wavelength, the passband, and the shape of the passband vary significantly from one kind of filter to another and one manufacturer to another.

### Background—Prior-Art—Viewing Color Images—FIG. 4

Scanned images are generally viewed on screensl 61 of monitors 160 (FIGS. 1 and 2). Monitor screens 161 vary widely in their construction. Liquid-crystal displays and cathode-ray tubes (not shown) use different means to project varying colors.

Liquid-crystal displays behave as optical filters. They are normally illuminated from behind by white light and each pixel on the screen passes colors which are determined by the voltage applied to the electrodes of that pixel.

Color cathode-ray tubes normally have a fine pattern of red, green, and blue phosphor dots arranged on the inner surface of their faceplate. In this case, each pixel comprises three dots; one each will glow red, green, and blue when individually addressed by an electron beam.

Normalized emission characteristics of the phosphors in a hypothetical monitor screen are shown in FIG. 4. Emission characteristics are defined as the center frequency and the wavelength spread of the emission at the 50% intensity point. (Again, the shape of the emission curves is somewhat important, but can be omitted here in the interest of simplicity.) In FIG. 4, the blue emission is centered at 460 nm with a spread from 450 to 470 nm. The green emission is centered at 530 nm with spread from 520 to 540 nm, and the red emission is centered at 620 nm with spread from 600 to 640 nm.

Some attempt has been made to standardize the red, green, and blue colors emitted by phosphors used in monitor screens. Still, there are variations from manufacturer to manufacturer. Similarly, the red, green, and blue light emitted by liquid-crystal displays from different manufacturers have different center wavelengths and passbands. Note also how the center wavelengths and bandwidths of the illumination source for scanning in FIG. 3 differ from those in FIG. 4 for the phosphors or liquid-crystals in screens used for viewing. All of these variations degrade the image as it passes from the scanner to the viewscreen.

### Background—Prior-Art—Color Correction—FIG. 5

Filter characteristics and emission characteristics vary widely and unpredictably from manufacturer to manufacturer. Because of this, it is necessary to employ color-correction algorithms to attempt to render the final image, viewed on screen 161 of monitor 160, with all the same colors as the original 100 placed on platen 105 (FIG. 1), or on film 210 (FIG. 2).

Most manufacturers of color scanners, monitors, printers, video equipment, and the like subscribe to standards of the International Color Consortium (ICC). The ICC was established in 1993 by eight imaging industry manufacturers. Their purpose has been to develop an open-to-all, standardized color management system for all color imaging and printing products. More information can be found on the ICC website at www.color.org.

To participate in the ICC standard, each manufacturer provides, along with its product, “driver” software which includes “device descriptions”. The driver software is stored in the memory of computer 155 (FIGS. 1 and 2) and used each time the computer accesses a device such as monitor 160, scanner 90 or 190, or a printer (not shown) for example. The device descriptions comprise numeric data that tell a computer subprogram called a color management module (CMM, not shown but well-known) how to interpret data and settings from individual devices. This information is all contained in a data file called the “ICC profile” of the device.

Viewing a scanned image through a common color space: A scanner 500 scans an image and transmits data from the scan to a computer 155. The computer applies the scanner's ICC profile 505 to the data, generating a new set of data for what is called a “common color space” or PCS 510. This action is often called “mapping” of one data set into another.

A monitor 520 is provided with its own ICC profile 515. The monitor's ICC profile is also stored in the memory of computer 155 to which the monitor is attached.

Additional corrections are available to the user through “user adjustment profiles” 507 and 512. These allow for subjective adjustments and minor adjustments to correct for unit-to-unit variability, such as from one same-model scanner to another.

Thus to view an image, the data must pass through two ICC profiles 505 and 515, two user profiles 507 and 512, and one PCS 510.

Passing through the PCS renders the viewed image as close as possible to the scanned image, within the accuracy of the ICC and user adjustment profiles and the PCS. While this is accepted practice, it is only an approximation. Variances in device performance contribute errors to the ICC profiles. Lack of precision in conversions from one set of data, through an ICC profile, through two user adjustment profiles, a common color space PCS, through a second ICC profile, and finally to the viewed data inherently contribute computational errors in colors seen in the final image. In addition, the ICC profile does not account for changes in color of the fluorescent lamp as it ages.

### Background—Prior-Art—Organic Light-Emitting Diodes (OLED)—FIG. 6

Recent advances in LED technology have led to the development of Organic LEDs (OLEDs). OLEDs are manufactured by many companies, including Eastman Kodak Company of Rochester, N.Y., USA, Sanyo of Japan, and others. At this time, OLEDs are contemplated for use in computer displays, television monitors, miniature displays, cellular telephone displays, and the like.

Unlike fluorescent lamps, OLEDs are flicker-free. The absence of flicker further reduces the requirement for image correction in a scanner. In addition, OLEDs do not require high-frequency, high-voltage power supplies. Thus scanner complexity and cost are reduced.

Instead of being constructed of layers of single-crystal semiconductor materials, OLEDs comprise a glass or plastic substrate 600 (the viewing screen), transparent anode electrodes 605, commonly indium-tin oxide, a hole injection layer 610, silk-screened or otherwise-deposited light-emitting layers 615, 620, and 625 which can emit light of red, green, and blue wavelengths respectively, an electron transport layer 630, and finally segmented metallic cathode electrodes 635, 640, and 645. Certain materials used in the manufacture of OLEDs are termed “organic” because they contain or have larger amounts of carbon compounds. The materials contained in these layers are beyond the scope of this discussion. More information can be found on the manufacturers' websites.

When a voltage, nominally 10 volts, is applied between electrodes 605 and 635 by source 650, layer 615 emits red light in the vicinity of the crossover of electrodes 605 and 635. When a voltage is applied between electrodes 605 and 640 (source not shown), green light is emitted in the vicinity of the crossover of electrodes 605 and 640. Similarly, when a voltage is applied between electrodes 605 and 645 (source not shown), blue light is emitted in the vicinity of the crossover of electrodes 605 and 645. The intensity of light emitted from an OLED device is presently about 400 (cd/m²). The emitted light is steady and flicker-free.

The ability to address individual red, green, and blue pixels this way makes possible a full-color display of virtually any size. The size of individual pixels is limited only by the deposition process. Pixel sizes in monitor displays typically range from 0.04 to 0.4 mm. The size of a viewing screen is limited only by practical considerations in depositing the various layers on substrate 600.

### Background—Prior-Art—U.S. Pat. No. 5,255,171—Clark

My U.S. Pat. No. 5,255,171 (1993) teaches an illumination system with intensification of initial source illumination. The preferred embodiment is a light concentrator for use with a color optical scanning device. The light concentrator employs non-imaging optics to concentrate light emanating from plural light-emitting diodes.

While feasible, this system required electrical connections to multiple, prior-art semiconductor light-emitting diodes, which were previously available only as small, individual devices.

### Background—Objects and Advantages

Accordingly, one object and advantage of the present invention is to provide an improved method and apparatus for scanning images and for viewing scanned images. Further objects and advantages are to provide a method and apparatus for illuminating objects being scanned with flicker-free illumination, for reducing image degradation due to the approximate nature of color correction algorithms and profiles, and for providing improved viewed image fidelity.

Additional objects and advantages will become apparent from a consideration of the drawings and ensuing description.

### SUMMARY

In accordance with the present invention, images are scanned and viewed using identical or nearly identical wavelengths. The same light-emitting technology is used in illuminating the object being scanned, and in viewing the scanned image. The close similarity of the scanning and viewing wavelengths virtually eliminates the need for color correction algorithms and profiles for color correction. If color correction is used, it can be either a null correction, or at most a very minor adjustment. The light-emitting technology is inherently flicker-free. Its spectral characteristics do not change with age. The result is improved fidelity between scanned and viewed images and greater digital depth. OLEDs are significantly more efficient than fluorescent lamps and can therefore operate at lower power levels for equivalent illumination.

### DRAWINGS-FIGURES

FIG. 1 is a cross-sectional view of a prior-art reflective, flatbed scanner.

FIG. 2 is a cross-sectional view of a prior-art transmissive scanner.

FIG. 3 is a plot showing hypothetical prior-art characteristics of filters used in scanning an image.

FIG. 4 is a plot showing hypothetical prior-art emission characteristics of phosphor-based and liquid-crystal-based viewing screens.

FIG. 5 is a block diagram showing the components in a prior-art color correction scheme.

FIG. 6 is a cross-sectional view of part of a prior-art OLED-based monitor screen.

FIG. 7 shows an OLED illuminator according to the present invention.

FIG. 8 is an end view of an OLED illuminator.

FIG. 9 shows an OLED illuminator illuminating an object.

FIG. 10 shows an OLED illuminator combined with a lens to illuminate an object.

FIG. 11 shows an OLED illuminator combined with non-imaging optics to illuminate an object.

FIG. 12 is an end view of a curved OLED illuminator.

FIG. 13 is an end view of a curved OLED illuminator with lenses over each emitter.

FIG. 14 shows two plots of emission characteristics of OLED illumination.

FIG. 15 shows a transmissive scanner system, according to the present invention.

FIG. 16 is a block diagram showing the data path between a scanner and a viewscreen, according to the present invention.

FIG. 17 is block diagram showing an alternative data path between a scanner and a viewscreen.

DRAWINGS—Reference Numerals

| | | | |
|---|---|---|---|
| 90 | Flatbed scanner | 160 | Monitor |
| 100 | Object | 161 | Screen |
| 105 | Platen | 190 | Film scanner |
| 110 | Source | 205 | Ray |
| 115 | Reflector | 207 | Reflector |
| 120 | Ray | 210 | Film |
| 125 | Ray | 220 | Lens |
| 130 | Mirror | 225 | Detector |
| 135 | Mirror | 230 | End |
| 140 | Mirror | 240 | Film |
| 145 | Lens | 500 | Scanner block |
| 150 | Detector | 501 | OLED scanner block |
| 155 | Computer or storage unit | 505 | Scanner ICC profile block |
| 507 | User adjustment block | 665 | Arrow |
| 510 | Common color space block | 680 | OLED screen |
| 512 | User adjustment block | 700 | Source |
| 515 | Monitor ICC profile block | 701 | Switch |
| 520 | Monitor block | 705 | Source |
| 521 | OLED monitor block | 706 | Switch |
| 600 | Substrate | 710 | Source |
| 605 | Anode electrodes | 711 | Switch |
| 610 | Hole injection layer | 790 | Scanner light source |
| 615 | Red emitter | 800 | OLED light source |
| 620 | Green emitter | 900 | Object |
| 625 | Blue emitter | 1000 | Lens |
| 630 | Hole transport layer | 1005 | Fiber-optic plate |
| 635 | Cathode | 1100 | Non-imaging optics |
| 640 | Cathode | 1101 | Exit |
| 645 | Cathode | 1200 | Curved source |
| 650 | Potential source | 1300 | Lenses |
| 655 | Arrow | | |
| 660 | Arrow | | |

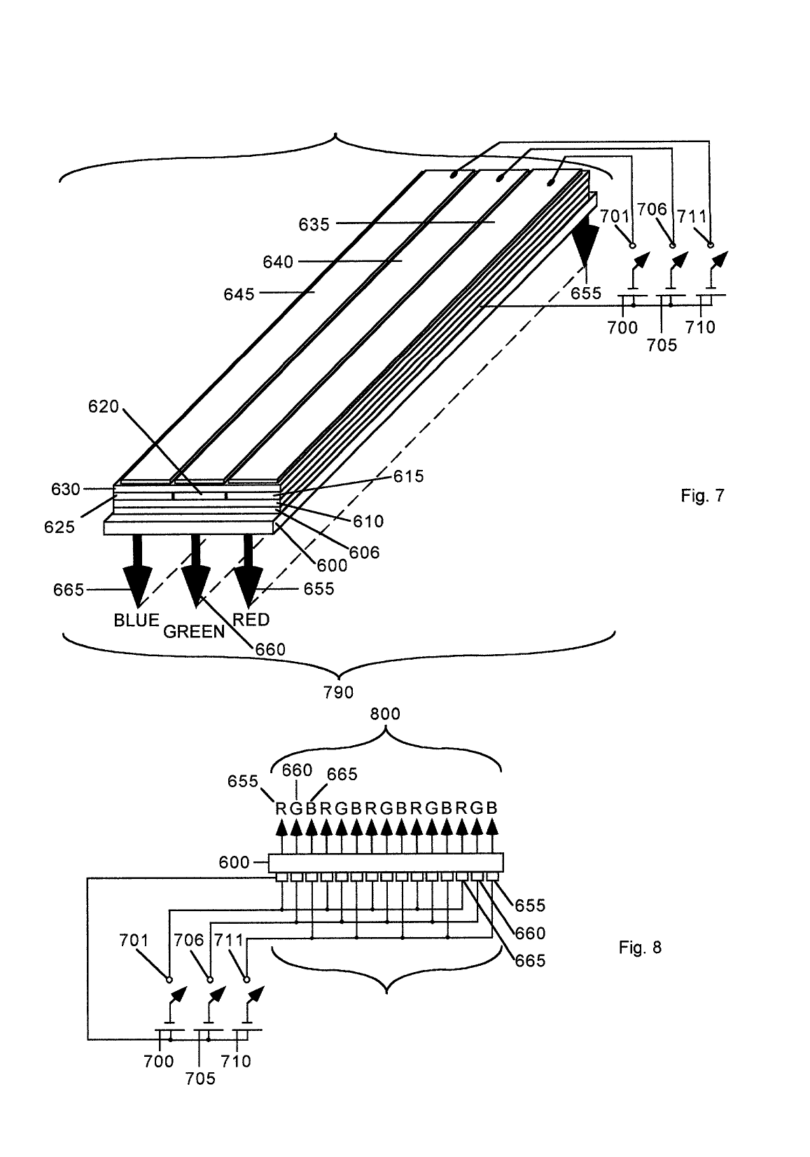

### DETAILED DESCRIPTION—PREFERRED EMBODIMENT—FIGS. 7 THROUGH 13—LIGHT SOURCE EMPLOYING ORGANIC LIGHT-EMITTING DIODES (OLEDs)

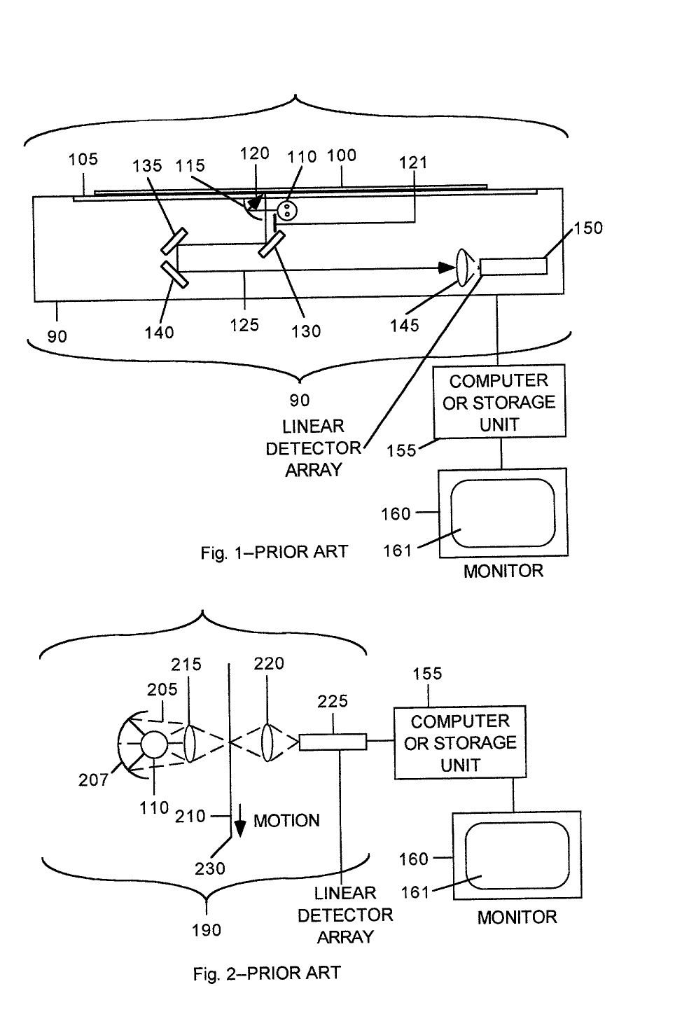

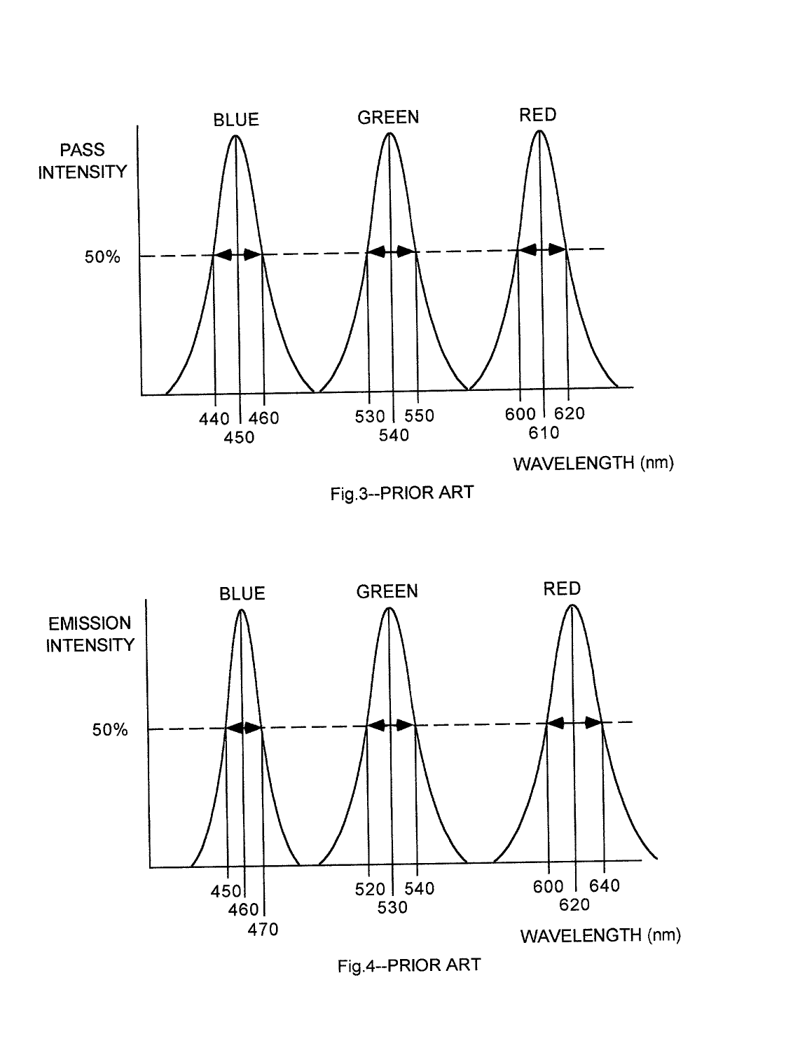

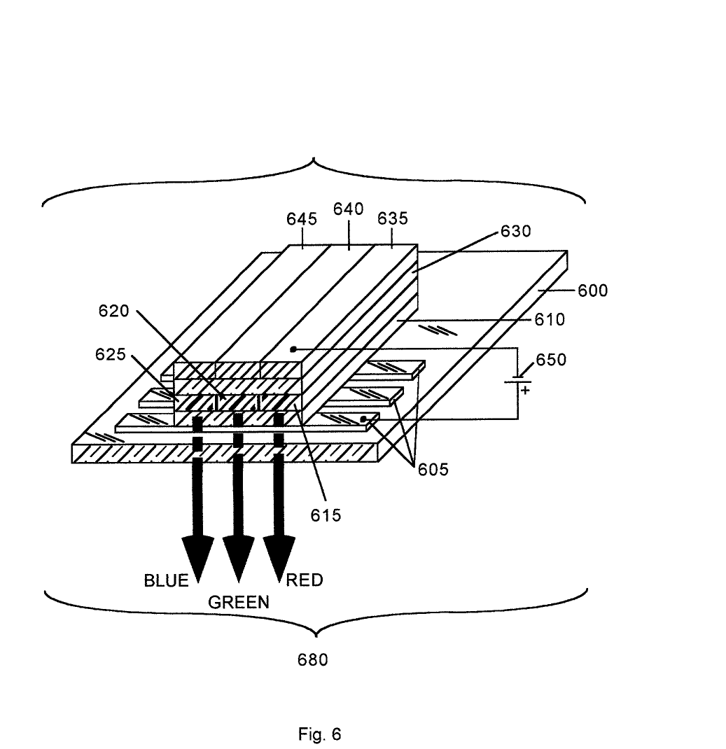

In the preferred embodiment, sources 800 (FIGS. 8 through 11) and monitor 160 (FIGS. 1 and 2) employ OLEDs with the same or similar spectral characteristics in each of light emitters 615, 620, and 625. Sources 800 replace sources 110 in scanners 90 and 190 (FIGS. 1 and 2). The phosphor or liquid-crystal display in screen 161 of monitor 160 (FIGS. 1 and 2) is replaced with an OLED screen 680 (FIG. 6). Images are scanned in the manner as described above in connection with FIGS. 1 and 2.

OLEDs can be used in as light sources for both viewing and illumination. An example of OLEDs used in a viewscreen is shown above in FIG. 6. An example of OLEDs used in a light source for a scanner is shown in FIG. 7. FIG. 7 is a perspective, not-to-scale, cross-sectional view of a simplified OLED light source 790 used in the present embodiment of the invention. Light source 790 contains all the elements of the source shown in FIG. 6, except that transparent segmented anode electrodes 605 are replaced by a continuous transparent electrode 606. Hole injection layer 610 and electron transport layer 630 have the same area as transparent electrode 606 in this embodiment. Instead of providing individual pixels of light, red, green, and blue emitters 615, 620, and 625, are now energized along their entire length, providing lines of light, as indicated by arrows 655, 660, and 665, respectively.

Source 790 is preferably 21.6 cm in length and 2.5 cm in width, although virtually any size is possible. The width of emitters 615, 620, and 625 is preferably 1 mm. Three emitters 615, 620, and 625 form a single bank of emitters. Instead of a single bank of three emitters, numerous banks of emitters can be laid side-by-side. The widths of the emitters is determined by the application in which they are used. Multiple banks are preferably connected in parallel so that all red emitters 615 operate simultaneously, all green emitters 620 operate simultaneously, and all blue emitters 625 operate simultaneously.

Emitters 615, 620, and 625 are energized by sources 700, 705, and 710, respectively when switches 701, 706, and 711 are closed. Sources 700, 705, and 710 typically provide a potential difference of ten volts. When switches 701, 706, and 711 are open, emitters 615, 620, and 625 are non-emissive. The common terminal of sources 700, 705, and 710 is connected to anode electrode 605.

FIG. 8 shows a preferred OLED light source 800 for use in a scanner or illuminator. FIG. 8 is an end view of the source shown in FIG. 7, with banks of the three emitters of source 790 repeated numerous times across the width of substrate 600. Sources 700, 705, and 710 provide electrical potential, nominally 10 volts, to energize red, green, and blue sections 655, 660, and 665, respectively when switches 701, 706, and 711 are closed.

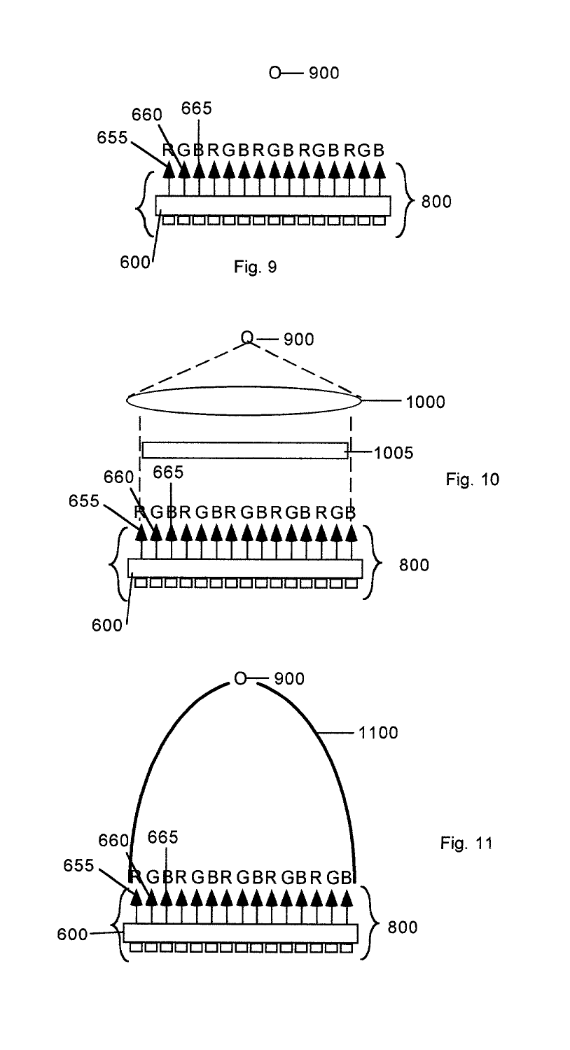

FIG. 9 shows source 800 in use without a lens or light concentrator. Object 900 is illuminated by source 800 with no attempt to focus or concentrate light beams 655, 660, and 665. Object 900 can be an opaque object 100 scanned in a reflective flatbed scanner (FIG. 1), a film 210 scanned in a transmissive film scanner (FIG. 2), or any object which is to be illuminated.

FIG. 10 shows source 800 in use with a lens. Lens 1000 focuses light beams 655, 660, and 665 on object 900, providing increased concentration of light. While a simple lens is shown, lens 1000 can be a cylindrical or even a compound lens. If further refinement is desired, other optics, such as a fiber-optic plate 1005 can be interposed between source 800 and lens 1000. Fiber-optic plates are well-known to those skilled in the art of optics.

FIG. 11 shows source 800 in use with a non-imaging concentrator 1100. This configuration delivers the highest light intensity to object 900. Concentrator 1100 is preferably designed according to my above-referenced patent U.S. Pat. No. 5,255,171, and associated references. Again, other optics (not shown) may be combined with source 800 and concentrator 1100.

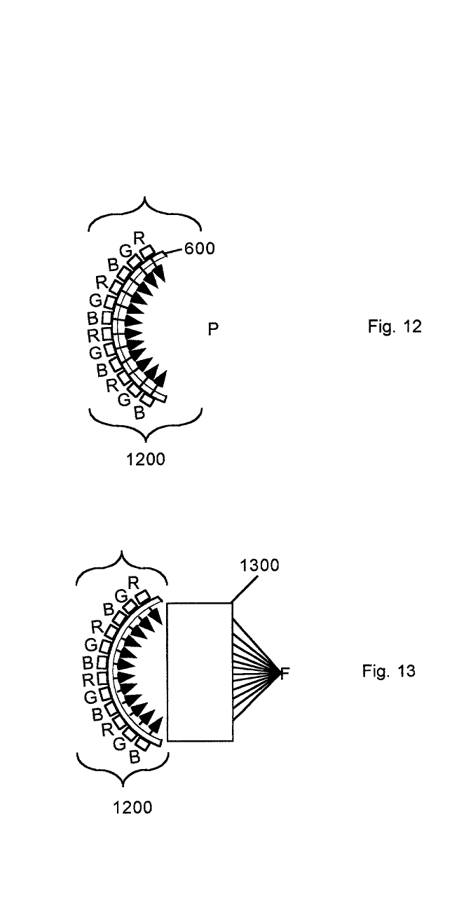

FIG. 12 shows source 1200, similar to source 800 but curved. In this embodiment, no lenses are used and light beams 655, 660, and 665 from sources 655, 660, and 665 are merely directed at a point P.

FIG. 13 shows source 1200 with the addition of unspecified optics 1300 over each of sources 655, 660, and 665. In this embodiment, light beams 655, 660, and 665 converge at a focal point F. The optics can comprise any combination of lenses or reflective surfaces.

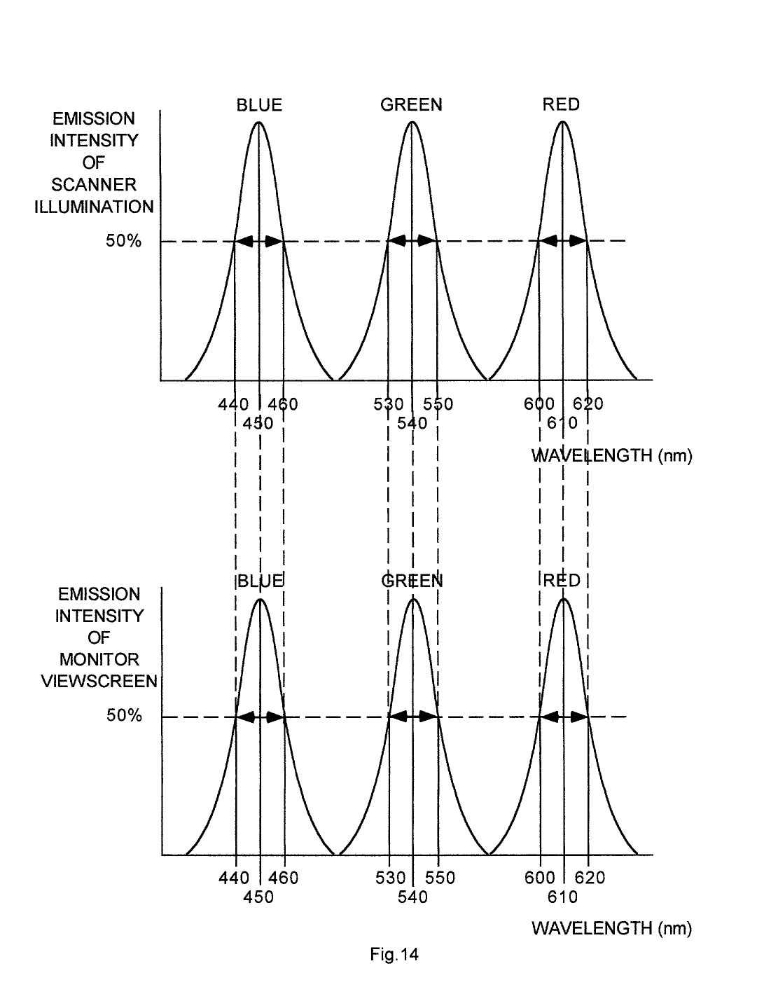

FIG. 14 contains two plots showing normalized emission intensity versus wavelength. The top half of FIG. 14 shows the emission spectrum of source 800, while the bottom half of FIG. 14 shows the emission spectrum of the screen 161 of monitor 160. The two are identical or nearly identical.

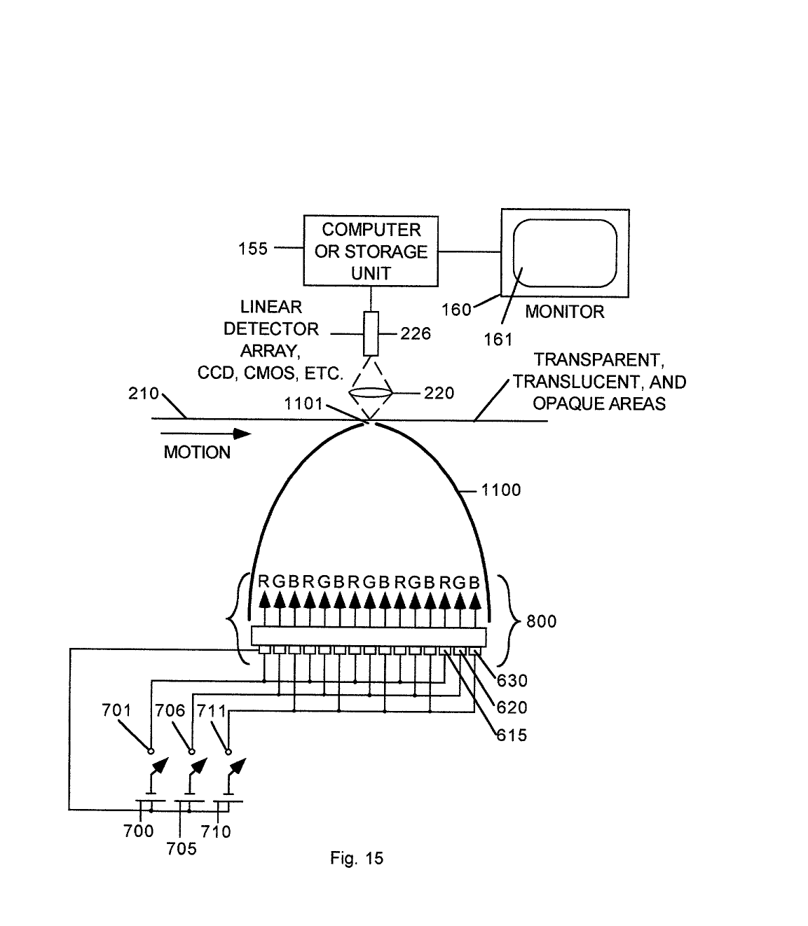

### Preferred Embodiment—FIGS. 15 through 17—Scanner with Light Source and Display Screen with Identical or Nearly Identical Emission Characteristics

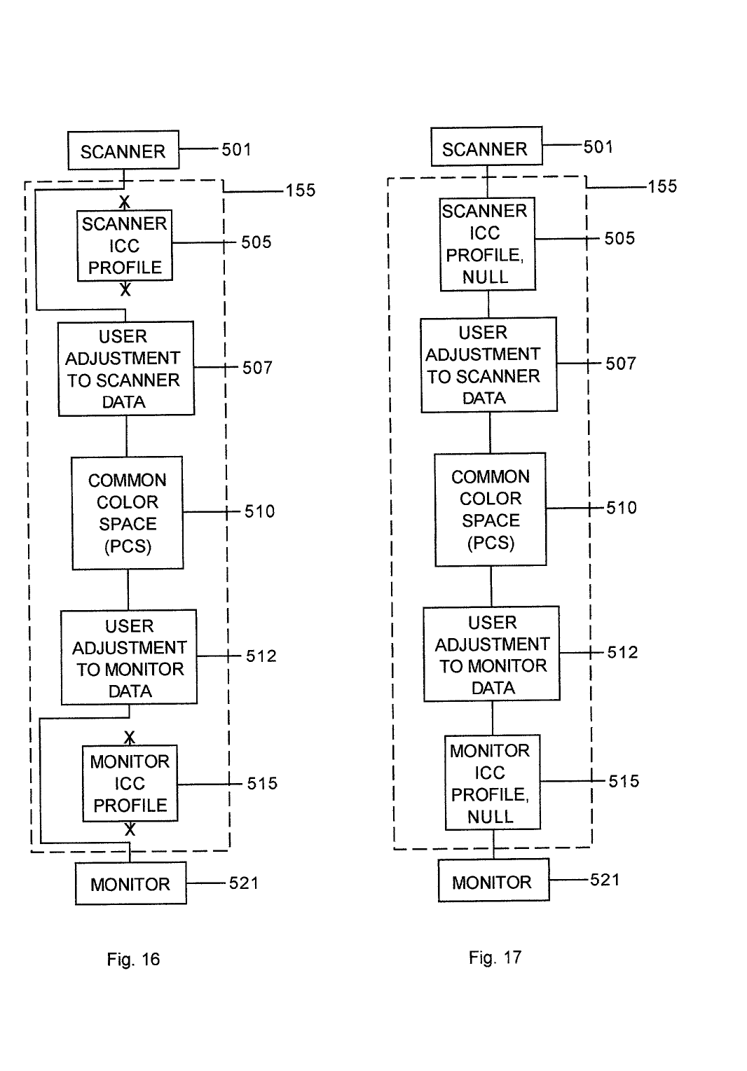

FIGS. 7 through 13 above show the structure of various OLED light sources for use in scanners. FIGS. 15 shows the use of an OLED light source 800 in a transmissive film scanner, along with monitor 160 with screen 161 which has emissive characteristics which are substantially the same as those of source 800. FIGS. 16 and 17 show the consequence of using source 800 to illuminate an image (not shown) on film 210, with screen 161 to view the image.

FIG. 15 shows a source 800 with red, green, and blue emitting segments 615, 620, and 630, which are selectively energized in same-color groups. Voltage which causes emitters 615 to emit is provided by potential source 700 when switch 701 is closed, and so forth.

Light from source 800 is reflected within non-imaging concentrator 1100 and impinges on film 210 at the exit 1101 of concentrator 1100. Transmitted light passes through film 210 and lens 220 and is detected by detector 226. The resulting data are adjusted as required, stored in computer 155, and viewed on screen 161 of monitor 160.

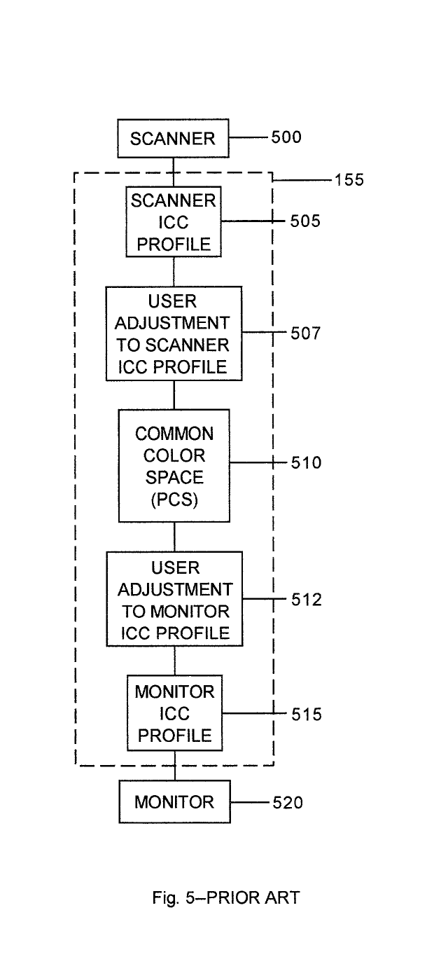

FIG. 16 is a block diagram showing operation of the preferred embodiment of my system. FIG. 16 is similar to FIG. 5, except that blocks 505 and 515 have been disconnected.

FIG. 17 is a block diagram similar to FIG. 16, with blocks 505 and 515 connected, allowing for minor adjustments to make subjective changes in the appearance of the final image viewed on screen 161.

### Operation—Preferred Embodiment—FIGS. 15 Through 17

A transmissive film scanner is shown cross-section in FIG. 15. Source 800 is coupled to a non-imaging reflector 1100 according to my above patent. Reflector 1100 concentrates light from OLED source 800 to a line across film 210. The image (not shown) in film 210 renders various areas of film 210 transparent, translucent, or opaque. Lens 220 focuses the line image on CCD, CMOS, or other linear photodetector array 226. No color filters are used between source 800 and array 226. Array 226 contains no filters; however its sensitivity is panchromatic, covering at least the spectral range of sources 615, 620, and 630.

The relative positions of source 800, lens 220, and detector 226 remain fixed. To begin a scan, a scanner transport (not shown but well known in the art) moves film 210 to its left-most position. An electronic switch 701 is closed, energizing all red OLED source segments 655. Light from segments 655 is funneled to film 210 at the focal point of lens 220. Detector 226 detects light from the red scan and passes representative data to computer 155 where it is stored. Next, switch 701 is opened, de-energizing red emitters. Then switch 706 is closed, energizing all green OLED source segments 660. Detector 226 detects light from the green scan and passes representative data to computer 155 where they are stored. Finally, switch 706 is opened and switch 711 is closed, de-energizing green emitters 660 and energizing blue emitters 665. Detector 226 detects light from the blue scan and passes representative data to computer 155 where they are stored. Next, film 210 is moved one scan line width (typically 0.025 mm) to the right and the red, green, blue detecting and storing process is repeated. This process continues until the entire region of interest on film 210 is scanned. Minor corrections can be made to the data at the end of each red-green-blue cycle, or after the entire image is saved. Although a film scanner is shown, the same source can be used in a flatbed scanner which is normally used to scan opaque objects.

With regard to FIG. 16, since the scanner 90 or 190 (block 501) and monitor 160 (block 521) have identical characteristics, there is no need to map the scanner's ICC profile (block 505) into the common color space (block 510) and then through the monitor ICC profile (block 515) before viewing the scanned image on monitor 160 (block 521). Performing such mapping twice is redundant since the spectral characteristics of the source 800 (FIGS. 8 through 11) and monitor 160 (FIGS. 1 and 2) are identical, or nearly so. In addition to being redundant, such mapping introduces round-off and other mathematical errors into image data, thus degrading the quality of the stored image.

Alternatively, as shown in FIG. 17, instead of removing the scanner and monitor ICC profiles (blocks 505 and 512, respectively), the profiles can be set as “null”, i.e. image data passes through these blocks unchanged.

No mathematical color adjustments are required to correct the image data obtained using source 800 before it is viewed on screen 161. Thus no errors are contributed to the color data as they pass through two ICC profiles and a common color space. The result is a true, high-fidelity image. The image viewed on screen 161 is identical to that contained in film 210, in the case of the transmissive film scanner, or on object 100, in the case of a flatbed scanner.

User adjustments to the scanner data (block 507) and monitor data (block 512) are still permitted to allow for subjective changes in appearance of the final image.

The common color space (block 510) can also be a “null” space since no adjustments to color data are required. Again, image fidelity is preserved since no mathematical mapping is done on any image data.

Conclusion, Ramifications, and Scope

It is thus seen that the present system provides a novel method and apparatus for highest fidelity scanning and viewing of images. Scanning and viewing using illumination with the same or nearly the same spectral characteristics removes the requirement for color correction in going from the scanner, through a computer or other storage device, to a monitor. The same spectral characteristics for scanning and viewing can be obtained using OLED light sources for both scanning and viewing illuminations. Using OLEDs as the light source for both scanning and viewing substantially improves the quality and digital depth of scanned images. Improved digital depth results from lack of flicker and removal of the requirement for profiling the scanner and the viewscreen. Greater digital depth in image data permits editing of these data while preserving image quality. Even if the OLEDs are used in a stand-alone scanner, without a monitor screen that has matching emission characteristics, the lack of spectral shift over time, as encountered in fluorescent lamps, results in the ability to more faithfully record scanned images over the long term. The ICC profile for the scanner doesn't change with time. Furthermore, the efficiency of OLEDs permits their use in low-power consumption applications, especially when compared with the relatively low efficiency of fluorescent lamps. In a system which filters the white fluorescent light, much of the spectral output of the lamp lies outside the passband of the filters and is therefore discarded. OLEDs, on the other hand, emit light at well-defined wavelengths and are therefore more efficient for use in scanning applications.

While the above description contains many specificities, these should not be considered limiting but merely exemplary. Many variations and ramifications are possible. For example, in the scanner, non-imaging optics can be combined with OLEDs to increase their light output, providing intensity greater than that of the OLED itself The illumination source can be curved or flat. More than three different colors of OLED can be used. Each group can have one or more sources or segments. The OLED segments can be small or large and can have different shapes. OLED segments can be interspersed with ordinary semiconductor LED devices.

While the present system employs elements which are well known to those skilled in the art of imaging, it combines these elements in a novel way which produces a new result not heretofore discovered.

Accordingly the scope of this invention should be determined, not by the embodiments illustrated, but by the appended claims and their legal equivalents.

I claim:

1. A system for scanning and viewing images, comprising:
a light source having a plurality of groups of source segments, each having one or more light-emitting segments, each segment arranged to emit a predetermined wavelength of light,
a plurality of potential sources for energizing said respective groups of segments,
a panchromatic scanner assembly for scanning an image with light from said light source and producing data representative of said image,
a computer or storage device for adjusting and storing said data and presenting said data to a screen, and
a screen having a plurality of groups of screen segments, each having one or more light-emitting segments for receiving said data and displaying said image represented by said data, said screen segments being arranged to emit light of substantially the same predetermined wavelengths as said source segments,
whereby said light source and said screen have substantially the same spectral emission characteristics, thus reducing the need for color correction between said light source and said screen.

2. The system of claim 1 wherein said light-emitting segments are organic light-emitting diodes.

3. The system of claim 1 wherein said predetermined wavelength is selected from the group consisting of red, blue, and green.

4. The system of claim 1 wherein said panchromatic scanner assembly contains a charge-coupled imaging device.

5. The system of claim 1 wherein said panchromatic scanner assembly contains a complementary metal-oxide semiconductor imaging device.

6. The system of claim 1 wherein said scanner assembly is arranged to scan an opaque object.

7. The system of claim 1 wherein said scanner assembly is arranged to scan a transparent object.

8. The system of claim 1 wherein said scanner assembly is arranged to scan a translucent object.

9. The system of claim 1 wherein said light source comprises a lens.

10. The system of claim 1 wherein said light source comprises a non-imaging optical device.

11. The system of claim 1 wherein said light source is a curved OLED array.

12. The system of claim 11, further including a lens positioned so that said individual emitter segments illuminate said object through said lens.

13. The system of claim 1 wherein each of said groups of source and screen segments contains three segments arranged to produce red, green, and blue light.

14. A method of scanning and viewing images, comprising:
providing a light source having a plurality of groups of source segments, each having one or more light-emitting segments, each arranged to emit a predetermined wavelength of light,
providing a plurality of potential sources for energizing said respective groups of segments,
providing a panchromatic scanner assembly for scanning an image with light from said light source and producing data representative of said image,
providing a computer or storage device for adjusting and storing said data and presenting said data to a screen, and
providing a screen having a plurality of groups of screen segments, each having one or more light-emitting segments for receiving said data and displaying said image represented by said data, said screen segments being arranged to emit light of substantially the same predetermined wavelengths as said source segments,
whereby said light source illuminates said object with substantially the same wavelengths as said screen uses to render the image of said object, thus reducing the need for color correction between said scanner assembly and said screen.

15. The method of claim 14 wherein said light-emitting segments are organic light-emitting diodes.

16. The method of claim 14 wherein said predetermined wavelength is selected from the group consisting of red, green, and blue.

17. The method of claim 14 wherein said panchromatic scanner assembly contains a charge-coupled device.

18. The method of claim 14 wherein said panchromatic scanner assembly contains a complementary metal-oxide semiconductor imaging device.

19. The method of claim 14 wherein said scanner assembly is arranged to scan opaque objects.

20. The method of claim 14 wherein said scanner assembly is arranged to scan transparent objects.

21. The method of claim 14 wherein said scanner assembly is arranged to scan translucent objects.

22. The method of claim 14 wherein said light source comprises a lens.

23. The method of claim 14 wherein said light source comprises a non-imaging optical device.

24. The method of claim 14 wherein each of said groups of source and screen segments contains three segments arranged to produce red, green, and blue light.

25. A light source for scanning or illuminating an object, comprising:
at least one group of source segments at least one of said segments being an organic light-emitting diode segment, said organic light-emitting diode segment arranged to emit a predetermined wavelength of light.

26. The source of claim 25 wherein said predetermined wavelength is selected from the group consisting of red, blue, and green.

27. The source of claim 25 further including a lens between said source and said object.

28. The source of claim 25 further including non-imaging optics between said source and said object.
